(19) United States
(12) Patent Application Publication
(10) Pub. No.: US 2017/0145566 A1
(43) Pub. Date: May 25, 2017

(54) CHEMICAL BATH DEPOSITION SYSTEM AND METHOD

(71) Applicant: NUVOSUN, INC., Milpitas, CA (US)

(72) Inventors: Preston CLOVER, Glendale, CA (US); Bruce D. HACHTMANN, San Martin, CA (US); Gang Grant PENG, Fremont, CA (US); Arthur C. WALL, Morgan Hill, CA (US)

(73) Assignee: NUVOSUN, INC., Milpitas, CA (US)

(21) Appl. No.: 15/319,521

(22) PCT Filed: Jun. 8, 2015
(86) PCT No.: PCT/US2015/034635

§ 371 Date: Dec. 16, 2016

Related U.S. Application Data
(60) Provisional application No. 62/013,224, filed on Jun. 17, 2014.

(51) Int. Cl. C23C 18/02; H01L 31/0392; H01L 31/18; H01L 31/0445; H01L 31/0224; C23C 18/12; H01L 31/0749

(52) U.S. Cl. CPC C23C 18/02; C23C 18/1291; H01L 31/03928; H01L 31/0749; H01L 31/0445; H01L 31/022466; H01L 31/1864

(57) ABSTRACT

Disclosed are methods and systems for forming a layer on a web with reduced levels of particulates. The layer is formed from a fluid mixture(s) or solution of chemical reagents that react to form the layer. The system includes a conveyor device provided configured to carry the web within the chamber while the first surface of the web undergoes one or more processing steps; a first fluid delivery apparatus and a second fluid delivery apparatus, and a first fluid removal apparatus. The first fluid removal apparatus is positioned within a space arranged between the first and the second delivery apparatuses.

### CROSS-REFERENCE TO RELATED APPLICATIONS

This application claims priority to U.S. Provisional Application No. 62/013,224, filed Jun. 17, 2014, the disclosure of which is hereby incorporated by reference in its entirety.

### BACKGROUND

1. Field of the Invention

The invention relates to systems and methods for forming layers of material on a web. More specifically, the invention relates to web-based chemical bath deposition.

2. Description of the Related Art

Solar cells are photovoltaic (PV) devices that convert sunlight directly into electrical energy. Solar cells can be based on crystalline silicon or thin films of various semiconductor materials that are usually deposited on low-cost substrates, such as glass, plastic, or stainless steel.

Thin film based photovoltaic cells, such as amorphous silicon, cadmium telluride, copper indium diselenide or copper indium gallium diselenide based solar cells, offer improved cost advantages by employing deposition techniques widely used in the thin film industry. Group IBIIIAVIA compound photovoltaic cells, including copper indium gallium diselenide (CIGS) based solar cells, have demonstrated significant potential for high performance, high efficiency, and low cost thin film PV products.

As illustrated in FIG. 1, a conventional Group IBIIIAVIA compound solar cell 10 can be built on a substrate 11 that can be a sheet of glass, a sheet of metal, an insulating foil or web, or a conductive foil or web. A contact layer 12 such as a molybdenum (Mo) film may be deposited on the substrate as the back electrode of the solar cell. An absorber thin film 14 including a material in the family of Cu(In,Ga)(S,Se)₂ may then be formed on the conductive Mo film. The substrate 11 and the contact layer 12 form a base layer 13. Although there are other methods, Cu(In,Ga)(S,Se)₂ type compound thin films can be formed by a two-stage process where the components (components being Cu, In, Ga, Se and S) of the Cu(In,Ga)(S,Se)₂ material are first deposited onto the substrate or a contact layer formed on the substrate as an absorber precursor, and are then reacted with S and/or Se in a high temperature annealing process.

After the absorber film 14 is formed, transparent layers 15 including a buffer film or layer, such as CdS, and a transparent conductive layer, such as an undoped-ZnO/doped-ZnO stack or an undoped-ZnO/In—Sn—O (ITO) stack, can be formed on the absorber film. In manufacturing the solar cell, the buffer layer is often first deposited on the Group IBIIIAVIA absorber film 14 to form an active junction. Then the transparent conductive layer is deposited over the buffer layer to provide the needed lateral conductivity. Light enters the solar cell 10 through the transparent layer 15 in the direction of the arrows 16. The above described conventional device structure is called a substrate-type structure. In the substrate-type structure light enters the device from the transparent layer side as shown in FIG. 1.

Various buffer layers with various chemical compositions have been evaluated in solar cell structures. CdS, ZnS, Zn—S—OH, Zn—S—O—OH, ZNO, Zn—Mg—O, Cd—Zn—S, ZnSe, In—Se, In—Ga—Se, In—S, In—Ga—S, In—O—OH, In—S—O, In—S—OH, etc. are some of the buffer layer materials that have been reported in the literature. Buffer layers for Group IBIIIAVIA devices such as CIGS(S) solar cells have various thicknesses, often falling within a range of 30-200 nm, and may be deposited by various techniques such as evaporation, sputtering, atomic layer deposition (ALD), electrodeposition and chemical bath deposition (CBD).

Chemical bath deposition (CBD) is a commonly used method for the formation of buffer layers on CIGS(S) absorber films. These techniques typically involve preparation of a chemical bath comprising the reagents of the buffer layer to be formed. The temperature of the bath can be raised, for example a range of 50-90° C. and the surface of the CIGS(S) film is exposed to the heated bath. Alternately, the substrate containing the CIGS(S) film may be heated and then dipped into the chemical bath kept at a lower temperature. A thin buffer layer grows onto the CIGS(S) film as a result of chemical reactions resulting from the application of heat to the bath and/or to the substrate carrying the CIGS(S) film.

An exemplary CBD process for the growth of a cadmium sulfide (CdS) buffer layer employs a chemical bath comprising cadmium (Cd) species (from a Cd salt source such as Cd-chloride, Cd-sulfate, Cd-acetate, etc.), sulfur (S) species (from a S source such as thiourea) and a complexing agent (such as ammonia, triethanolamine (TEA), diethanolamine (DEA), ethylene diamine tetra-acetic acid (EDTA), etc) that regulates the reaction rate between the Cd and S species. Once the temperature of such a bath is increased to the desired temperature, the reaction between the Cd and S species takes place everywhere in the solution. As a result, a CdS layer forms on all surfaces wetted by the heated solution; in addition CdS particles tend to form within the solution. CBD deposition of the CdS layer often includes unwanted CdS particulates, which can lead to reduced cell efficiency and other problems, for example, reduced junction formation with the subsequently formed transparent layers of the cell structure.

Chemical bath deposition of Cadmium sulifide layers results in high conversion efficiencies for CIGS solar cells. However, its use in high volume manufacturing is, as discussed above, often problematic. Therefore, there is still a need to improve CdS deposition techniques in producing CIGS solar cell devices.

### SUMMARY OF THE INVENTION

The present invention provides methods for forming layers of material on a web, and more specifically for depositing CdS layers on thin films, for example, IB-IIA-VIA thin films.

In one aspect, the invention provides a system for forming a layer of material on a web, wherein the web has a first surface and a second surface opposite the first surface, the system comprising a conveyor device configured to carry the web while the first surface of the web undergoes one or more processing steps; a first fluid delivery apparatus and a second fluid delivery apparatus, the first and the second fluid delivery apparatuses being positioned above the conveyor device, wherein the first and the second fluid delivery apparatuses are configured to deliver one or more fluids onto the first surface of the web; and a first fluid removal apparatus, the first fluid removal apparatus being positioned within a space arranged between the first and the second delivery apparatuses. In certain embodiments, the system is contained within an enclosure or chamber.

In another aspect, the invention provides a process for forming a layer of material on a web, wherein the web has a first surface and a second surface opposite the first surface, the process comprising moving the web within an enclosure for carrying out one or more processing steps on the web; delivering a first fluid to the web via a first fluid delivery apparatus; removing a portion of the first fluid from the web via a first fluid removal apparatus comprising a suction device; subsequent to removing a portion of the first fluid, delivering a second fluid to the web via a second fluid delivery apparatus comprising a suction device; and forming a layer of material on the web.

The system and method of the invention, in particular, the removal of portions of the first and second fluids from the web as described herein produces a web having a continuous layer of deposited material with a reduced amount of particulates.

The invention also permits deposition of two or more different layers onto a web by a single pass through one tool or apparatus.

The foregoing summary is illustrative only and is not intended to be in any way limiting. In addition to the illustrative aspects, embodiments, and features described above, further aspects, embodiments, and features will become apparent by reference to the figures and the following detailed description.

### BRIEF DESCRIPTION OF THE DRAWINGS

FIG. 1 is a schematic side view of a thin film solar cell including a Group IB-IIIA-VIA compound absorber layer.

FIG. 2A illustrates a system for processing a web, in accordance with an example embodiment.

FIG. 2B illustrates a portion of the system shown in FIG. 2A, in accordance with an example embodiment.

FIG. 3 illustrates a conveyor belt disposed between the processing bed and the web, in accordance with an example embodiment.

FIG. 4A illustrates a system including first and second fluid delivery apparatuses, a fluid removal apparatus, a rinse apparatus, and heating apparatuses 606, in accordance with an example embodiment.

FIG. 4B illustrates a system including first and second fluid delivery apparatuses, first and second fluid removal apparatuses, a rinse apparatus, and heating apparatuses 606, in accordance with an example embodiment.

FIG. 5 illustrates a fluid delivery apparatus for dispensing a stream of a first fluid of the fluid mixture and a stream of a second fluid of the fluid mixture onto a cascade device, in accordance with an example embodiment.

FIG. 6 illustrates a fluid removal apparatus for removal of residual material and debris, in accordance with an example embodiment

### DETAILED DESCRIPTION

The following detailed description describes various features and functions of the disclosed systems and methods with reference to the accompanying figures. In the figures, similar symbols identify similar components, unless context dictates otherwise. The illustrative system and method embodiments described herein are not meant to be limiting. It may be readily understood that certain aspects of the disclosed systems and methods can be arranged and combined in a wide variety of different configurations, all of which are contemplated herein.

The terms “photovoltaic cell” (also “solar cell” herein), as used herein, generally refers to a device comprising a photoactive material (or absorber) that is configured to generate electrons (or electricity) upon exposure of the device to electromagnetic radiation (or energy), or a given wavelength or distribution of wavelengths of electromagnetic radiation. Solar cells may be electrically connected in series with other similar solar cells to raise the voltage levels and minimize resistive losses that would otherwise occur due to high currents. In some examples, a large number of solar cells can be serially connected and integrated into solar modules that are several meters long.

Forming photovoltaic cells may involve making use of thin-film, light-absorbing semiconductor materials. An example photovoltaic cell may include a stainless steel web substrate. The stainless steel web substrate may be a flexible substrate. In an example, processing the stainless steel web substrate to form the photovoltaic device may include forming a molybdenum (Mo) layer on a backside of the stainless steel web substrate. Thereafter processing may occur on a front side of the stainless steel substrate. For instance, a chromium (Cr) layer may be formed adjacent to the substrate and a Mo layer may be formed over the Cr layer. An absorber layer that in the cell converts light to electricity may be the next layer. This is typically a p-type layer. Preferred absorbers are copper chalcogenides, such as copper indium selenides, sulfides or selenide sulfide (together referred to as CIS layers). Copper indium gallium selenides (CIGS) are preferred. The absorber layer may be doped with sodium (Na). An n-type layer may be formed as a buffer layer over the absorber layer. Cadmium sulfide (CdS) buffer layer is preferred. The method of this invention is suitable for use in forming this buffer layer.

In examples, forming the component layers of the photovoltaic cell may involve a plurality of roll-to-roll deposition systems or stages. As an example, in a first stage, the backside of a stainless steel web substrate is coated with a back side Mo layer, and the front side of the stainless steel substrate is coated with a back electrode Cr/Mo, an alkali metal sodium fluoride (NaF) layer, and a precursor CIGs layer. Within a second stage, the CIGs precursor may be fully reacted to form photoactive CIGS. In a third stage, the CdS buffer layer may be deposited. In a fourth stage, a transparent oxide layers (ZnO/TCO) may be deposited.

In certain embodiments, the system for forming the layers of material on a web is enclosed within a chamber.

These stages, systems, or processing steps are examples for illustration only. More or less steps/stages may be used and different material can be used to form a given photovoltaic cell. Forming a buffer layer on top of a web-based photovoltaic absorber layer (e.g., forming a CdS layer) typically involves depositing a solution or fluid mixture on the web and the absorber layer coupled thereto. Depositing the fluid mixture to form a uniform buffer layer over the web may involve multiple challenges. As discussed above, for example, the reagents in the solution used to form the CdS layer react and form the CdS layer on the substrate, but also form CdS particles within the solution.

Disclosed herein are methods and systems that can address the aforementioned challenges. The methods and systems involve depositing the desired layer in multiple solution application steps, and removing a portion of each solution between application steps. The invention produces a continuous layer of deposited material having a reduced amount of particulates . Where the system is used to deposit a buffer layer of CdS on a substrate for production of a photovoltaic cell, the resulting deposited layer of CdS possesses excellent cell efficiency permits high quality junction formation with the subsequently formed transparent layers of the cell structure.

The methods and systems are described in the context of photovoltaic cells as an example for illustration only. The methods and systems described herein generally relate to depositing any type of layer over any type of web.

In this example, the web has a first surface (where the formation of a CdS layer or a different material deposited by chemical bath deposition or other processing occurs, for example) and a second surface opposite the first surface. In particular embodiments, the web can be a stainless steel, such as a a magnetic form of stainless steel.

The system of the invention includes support for the web, where support is provided by a processing bed arranged so that the first surface of the web may undergo one or more processing steps.

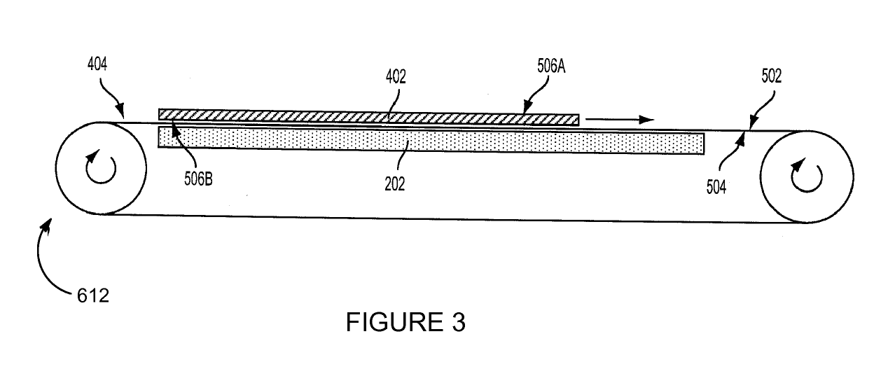

FIG. 2A illustrates a system 200 for processing a web, in accordance with an example embodiment. FIG. 2A depicts system (or apparatus) 200 that may include a plurality of processing stages for the web. The system 200 may be configured for depositing a layer from a chemical fluid mixture bath on a web. Thus, the system 200 may be referred to as chemical bath deposition system or apparatus. FIG. 2B illustrates a portion of the system 200, in accordance with an example embodiment. As shown, the portion of system 200 includes a processing bed 202 underneath one or more processing systems 203. The web from roll 201 may be conveyed through system 200 such that the web is supported by the processing bed 202 while it undergoes processing by the one or more processing systems 203.

The method includes moving the web over the processing bed using a conveyor device comprising a conveyor belt The conveyor belt has a first contact surface and a second contact surface opposite the first contact surface. The first contact surface is configured to contact the second surface of the web, and the second contact surface is configured to contact the processing bed.

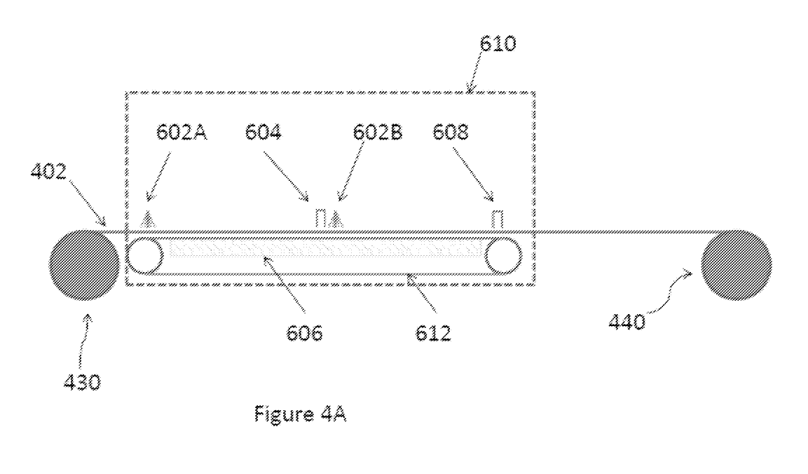

FIG. 3 illustrates a conveyor device 612 comprising conveyor belt 404 disposed between the processing bed 202 and a section of the web 402, in accordance with an example embodiment. The conveyor belt 404 has a first contact surface 502 and a second contact surface 504 opposite the first contact surface 502. The web 402 has a first surface 506A and a second surface 506B opposite the first surface. The first surface of the web 402 may be facing upwards and may undergo several processing steps as described below with respect to the method 600. The second surface of the web 402 may be configured to contact the first contact surface 502 of the conveyor belt 404. The second contact surface 504 is configured to contact the processing bed 202 as shown in FIG. 3.

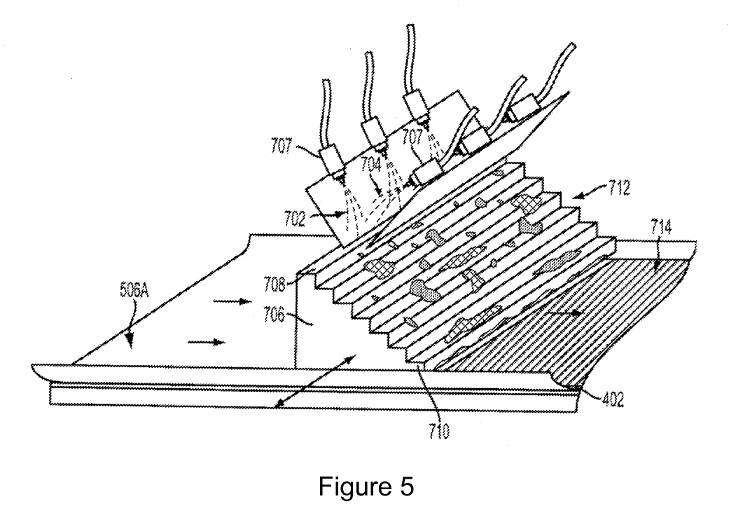

In examples, the first contact surface 502 of the conveyor belt 404 may be configured to have a high coefficient of friction so as to apply traction to the second surface 506B of the web 402 such that the web 402 moves along with the conveyor belt 404. The second contact surface 504 of the conveyor belt 404 may have a low coefficient of friction (e.g., lower than the coefficient of friction of the first contact surface 502) so as to slide over and move relative to the flat surface of the processing bed 202. Thus, as the conveyor belt 404 moves/rotates, the web 402 moves with the conveyor belt 404 while the processing bed 202 remains stationary. Although the conveyor belt 404 is shown in FIG. 5 to move in a certain direction (e.g., rotation in clockwise direction), in other cases the conveyor belt 404 and the web 402 may move in an opposite direction.

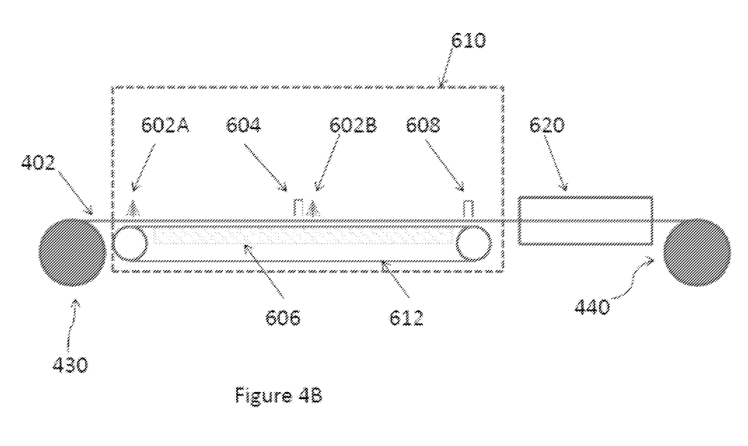

As shown in FIG. 4A, the system of the invention is optionally contained within an enclosure or chamber 610. Although containment within an enclosure is not required, the following discussion reflects an embodiment of the invention wherein the system is contained within an enclosure or chamber. Various configurations of an enclosure(s) are encompassed by this disclosure.

FIG. 4A depicts an apparatus comprising a pay out (or payout) roll 430 and a take-up (or uptake, pickup) roll 440. Web 402 can be delivered from payout roll 430 to the system, carried by conveyor device 612 for processing by the system, and taken up on take-up roll 440.

As shown in FIG. 4A, the system includes a first fluid delivery apparatus 602A and a second fluid delivery apparatus 602B. In one example, the first and the second fluid delivery apparatuses are positioned within the chamber above conveyor device 612, wherein the first and the second fluid delivery apparatuses are configured to deliver one or more fluids onto the first surface of the web. The first and second fluid delivery apparatuses, as shown in FIG. 4A, are arranged so that space exists between these apparatuses.

The first and second fluid delivery apparatuses can be independently selected from a variety of devices suitable for applying a fluid to a moving web.

For example, the fluid delivery apparatuses can be spreader boxes, for example gravity feed spreader boxes, having a longitudinal gap that can be adjusted to control the amount of fluid applied to the web. The spreader boxes are typically gravity feed spreader boxes, but can be pressurized if desired.

The fluid delivery apparatuses alternatively may be a device fitted with a plurality of nozzles arranged to supply fluid to the moving web.

In an alternative embodiment, a fluid delivery apparatus may include a cascade device. As depicted in FIG. 5, a cascade device has an upper level, a lower level positioned above the web, a plurality of steps between the upper level and the lower level, and can be configured to vibrate. A first fluid and a second fluid are dispensed onto the upper level of the cascade device, such that (i) the first and second fluids cascade down the steps to the lower level and onto the web and (ii) the first and second fluids are at least partially mixed by the cascade and by vibration of the cascade device prior to reaching the web. Where the first and second fluids contain reagents for, e.g., forming a CdS layer of material in a photovoltaic devices, the reagents will be prevented from reacting until they mix during their cascade down the steps of the cascade device.

FIG. 5 illustrates a fluid delivery apparatus including a dispenser for providing a stream of a first fluid and a stream of a second fluid 704 onto a cascade device 706, in accordance with an example embodiment. The fluid delivery apparatus may include a chemical dispenser device, such as nozzles 707 shown in FIG. 5, configured to dispense the stream of the first fluid 702 and the stream of the second fluid 704 onto the cascade device 706. The cascade device 706 may have an upper level 708 and a lower level 710 positioned above the web 402 (e.g., at a predetermined distance from the first surface 506A of the web 402). The cascade device 706 may also include a plurality of steps 712 between the upper level 708 and the lower level 710.

Further, the cascade device 706 may be configured to vibrate. For example, the cascade device 706 may be configured to oscillate in a lateral, longitudinal, vertical direction or a combination thereof. The cascade device 706 may be configured to vibrate at a predetermined frequency or according to a predetermined frequency and direction profile over time. Any mechanism configured to cause vibration of the cascade device 706 can be used. The mechanism, for example, could utilize an electric system (e.g., electric motors), a hydraulic system, an electro-mechanical system, an electro-hydraulic system, etc. to cause the cascade device 706 to vibrate.

In this manner, as the stream of first fluid 702 and the stream of the second fluid 704 are dispensed onto the upper level 708 of the cascade device 706, the first fluid 702 and second fluid 704 cascade down the steps 712 to the lower level 710 and onto the web 402. Cascading the first fluid 702 and the second fluid 704 down the steps 712 while the cascade device 706 vibrates facilitates at least partial mixing of the fluids 702 and 704 prior to reaching the web 402. In one example, the first fluid 702 and the second fluid 704 may be fully mixed before reaching the web 402.

A fluid mixture 714 of the first fluid 702 and the second fluid 704 dispensed onto the web 402 may form a solution having a given thickness or depth, e.g., in the range of 1-10 millimeters, covering the first surface 506A of the web 402. Any fluid depth can be utilized based on the type of the web 402, the fluids being deposited, the layer to be created, etc.

In examples, any number of fluids can be mixed to form a layer on the web. The method is described herein using a mixture of two fluids as an example for illustration only. As an example for illustration, the first fluid may be a chemical solution including cadmium sulfate (CdSO4) and ammonia hydroxide (NH₄OH) while the second fluid may be a chemical solution including thiourea (SC(NH₂)₂). In this example, the resulting layer depositing on the web may thus include cadmium sulfide (CdS). Alternatively, a layer of zinc sulfide or indium sulfide could be formed by substituting either zinc sulfate (ZnSO₄) or indium sulfate (In₂(SO₄)₃ in place of the cadmium sulfate (CdSO₄). In one example, the first fluid and the second fluid may be mixed at mixing stations remote from the web surface and then transported as a ready to react mixture to a distribution nozzle or any other distribution means to be deposited on the surface of the web. However, overtime the mixture may interact with valves, pipes, components, etc. of the transportation system and may thus generate debris and contaminants that are mingled with the fluid mixture to be deposited on the web.

In another example, alternative to mixing the fluids at a remote station, the stream of the first fluid and the stream of the second fluid are each brought separately to a distribution head (e.g., including one or more nozzles) above the web, and are each individually presented onto a vibrating cascade that mixes the solutions just prior to their falling from the cascade onto the surface of the web. In this manner, no debris or contaminants are generated from interaction of an already reacting fluid mixture with components and transmission lines of the fluid transportation system.

In certain embodiments, the solution contains reagents that are designed to react and form a layer of cadmium sulfide, indium sulfide, or zinc sulfide on the web. Materials that may be used to form additional buffer layers on the web include In₃S₂, In(OH, S), ZnS, Zn(O, S), ZnCa(OH, S), ZnMg(OH, S), and CdO (for generating Cd(O,S)). In embodiments where the system and method are adapted for manufacturing photovoltaic cells having a CdS buffer layer, each fluid delivery apparatus delivers a solution containing a material comprising divalent cadmium. In some embodiments, the fluid mixtures or solutions dispensed by the fluid delivery apparatuses will be the same. In other embodiments, the fluid mixtures dispensed by the first fluid delivery apparatus is different than the fluid mixture dispensed by the second fluid delivery apparatus.

As further shown in FIG. 4B, the system includes a first fluid removal apparatus 604 positioned within chamber 610 and within the space between the first and the second delivery apparatuses. The first fluid removal apparatus may be arranged to remove a portion of the first fluid from the web prior to formation of a substantial number of particles in the first fluid on the web.

In certain embodiments, as shown in FIG. 4B, the system includes a second fluid removal apparatus 608. Second fluid removal apparatus 608 is positioned within chamber 610 and arranged to remove fluid delivered by second fluid delivery apparatus 602B. As with the first fluid removal apparatus, the second fluid removal apparatus may be arranged to remove a portion of the second fluid from the web prior to formation of a substantial number of particles in the second fluid on the web. In this manner, removal of portions of the first and second fluids from the web as described herein produces a web having a continuous layer of deposited material with a reduced amount of particulates and may have a relatively thinner cross-section compared with single application processes.

Additional fluid delivery apparatuses and fluid removal apparatuses may be included in the system when necessary.

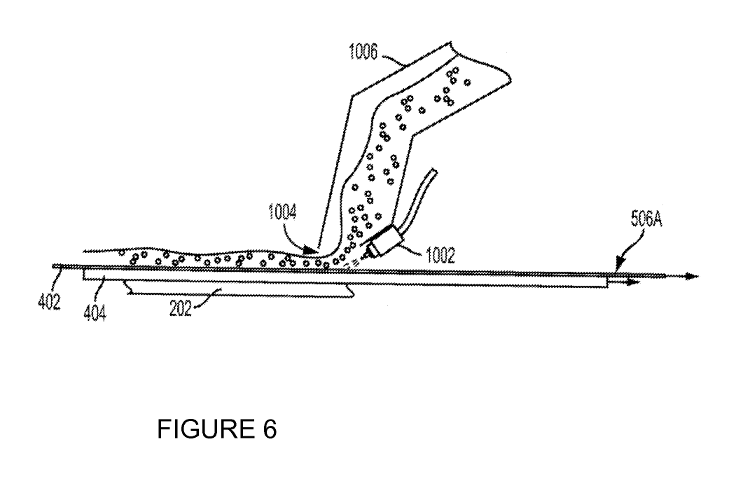

The first and second fluid removal apparatuses may be the same type of device or may be different types. In certain embodiments, the fluid removal apparatuses comprise suction devices. Suitable suction devices include vacuum heads attached to a vacuum apparatus via suitable piping or tubing. As shown in FIG. 6, the vacuum head 1004 may be configured to apply suction at a predetermined height above the web 402. The rinsing fluid dispensed by the nozzle 1002 may locally raise the liquid level of the excess fluid to at least the predetermined height above the web 402. The suction applied by the vacuum head 1004 pulls the fluid up in a substantially perpendicular direction to the first surface 506A of the web 402. The material pulled up by the vacuum head 1004 enters a vacuum manifold 1006 and is transported through the vacuum manifold 1006 to, for example, a waste collection compartment. Thus, excess fluid and particles are removed and are not left to contaminate the surface of the web 402.

In particular embodiments, the first fluid delivery apparatus delivers fluid to the web at a rate sufficient to produce a fluid layer on the web having a depth of at least about 1 mm. Subsequent to removal of a portion of the first fluid, the second fluid delivery apparatus delivers fluid at a rate sufficient to produce a layer of the second fluid on the web having a depth of at least about 1 mm. The depth of the second fluid layer may be the same or different than the depth of the first fluid layer. In particular embodiments, the layer of the first fluid prior to portion removal may have a depth of about 3-4 mm, such as about 3.5 mm. The layer of the second fluid prior to portion removal may also have depth of about 3-4 mm, such as about 3.5 mm.

As also shown in FIG. 4, the system may include one or more heating apparatus 606 within the chamber. In particular embodiments, the heating apparatus 606 is configured to directly or indirectly heat the web as it undergoes the one or more processing steps. In other embodiments, heating apparatus 606 is configured to heat the fluid mixture prior to delivery to web 402. This may be carried out by heating the fluid delivery apparatus or the reagent solutions provided to the fluid delivery apparatus. In still further embodiments, the heating apparatus may be configured to simultaneously provide heat to the fluid delivery fluid mixture and to the web.

One or more heaters may be used to indirectly heat the web by heating the processing bed 202. In some examples, the processing bed 202 may be divided into separate sections, each section being heated to a respective temperature. As an example for illustration, a section of the processing bed 202, where the cascade device 706 is disposed and the fluid mixture 714 is dispensed onto the web 402, may be heated to an elevated temperature. As the web 402 moves to other sections of the processing bed 202, temperature may be raised gradually to create a temperature gradient that facilitates chemical reaction within the fluid mixture 714. For instance, a following section may be heated to a temperature of 65° C.-90° C. To cause different sections of the processing bed 202 to be heated to different temperature without causing heat to be transferred from section to another, thermal dividers can be used to thermally isolate individual sections of the processing bed 202 from each other.

The system also may include a rinse apparatus 620 within the chamber and positioned adjacent to the second fluid removal apparatus and opposite the space arranged between the first and the second delivery apparatuses. Rinse apparatus 620 may be configured to dispense a rinsing fluid or rinsate onto web 402 as the web 402 moves (via conveyor belt 404). In certain embodiments, rinse apparatus 620 comprises a plurality of nozzles can be used to dispense a rinsing fluid or rinsate and may be arranged across the width of the conveyor belt. Suitable rinsates are, for example, deionized water, surfactant, or any number of fluids or mixtures.

FIG. 6 illustrates an example embodiment of a fluid removal apparatus for removal of residual material and debris arranged immediately adjacent a rinsing device. Thus, in this embodiment, the fluid removal apparatus can be considered to include a rinsing device and a suction device. FIG. 6 depicts a combination of a nozzle 1002 (as an example rinsing device) and a vacuum head 1004 (as an example suction device) configured for removal of residual material and debris from the surface of the web 402. Although one nozzle 1002 is depicted in FIG. 6, a plurality of nozzles can be used to dispense a rinsing fluid or rinsate. For example, the rinsate could include deionized water, surfactant or any number of fluids or mixtures.

The nozzle 1002 may be configured to dispense the rinsing fluid or rinsate on the web 402 as the web 402 moves (via the conveyor belt 404). As the nozzle 1002 dispense the rinsing fluid onto the surface of the web 402, the rinsing fluid forms a standing wave (or dam) that raises liquid level of the excess fluid locally as shown in FIG. 6. The rinsing fluid also loosens or knocks excess particles off of the first surface 506A of the web 402 and/or surface of the formed layer.

The vacuum head 1004 may be configured to apply suction at a predetermined height above the web 402. The rinsing fluid dispensed by the nozzle 1002 may locally raise the liquid level of the excess fluid to at least the predetermined height above the web 402. The suction applied by the vacuum head 1004 pulls the fluid up in a substantially perpendicular direction to the first surface 506A of the web 402. The material pulled up by the vacuum head 1004 enters a vacuum manifold 1006 and is transported through the vacuum manifold 1006 to, for example, a waste collection compartment. Thus, excess fluid and particles are removed and are not left to contaminate the surface of the web 402.

The system may include more modules or apparatuses for further processing. For instance, the system may include a cleaning apparatus configured to clean the web 402 and the layer formed thereon via any type of suitable cleaning solution. In another example, the system may include a drying apparatus configured to dry (e.g., via an air knife or any other device) the web 402 and the layer formed thereon. In particular, the system of the invention may include a drying apparatus within the chamber and positioned adjacent the rinse apparatus opposite the second fluid removal apparatus.

Further, in some examples, the system may include a variety of sensors that might be installed along the path that the web 402 travels through the system 200. As examples, the system 200 may include a thickness sensor configured to detect thickness of the coated web 402. The system may also include an optical sensor configured to detect surface imperfections on the layer formed on the web 402. Other sensors may be configured to detect chemical composition either on surface and/or through depth of coating and the system 200 may be configured to control dispensing the first fluid 702 and the second fluid 704 (FIG. 5) accordingly. These sensors are examples for illustration only, and other types of sensors can be used in the system.

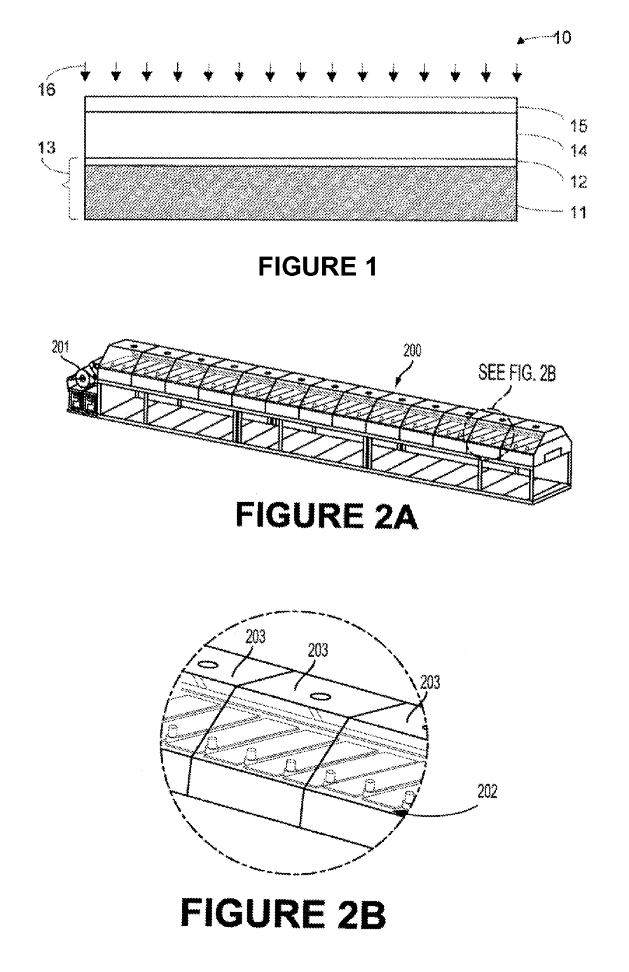

The methods and systems described in FIGS. 1-6 may be implemented to form a buffer layer (e.g., CdS) in a solar cell from fluid mixtures deposited onto a moving web. However, the methods and systems described in FIGS. 1-6 can be used to form any type of liquid layer onto a moving web of any type for chemical reaction or film deposition or a combination of both.

While the present method and/or apparatus has been described with reference to certain implementations, it will be understood by those skilled in the art that various changes may be made and equivalents may be substituted without departing from the scope of the present method and/or apparatus. In addition, many modifications may be made to adapt a particular situation or material to the teachings of the present disclosure without departing from its scope. Therefore, it is intended that the present method and/or apparatus not be limited to the particular implementations disclosed, but that the present method and/or apparatus will include all implementations falling within the scope of the appended claims.

1. A system for forming a layer of material on a web, wherein the web has a first surface and a second surface opposite the first surface, the system comprising:
a conveyor device configured to carry the web while the first surface of the web undergoes one or more processing steps;
a first fluid delivery apparatus and a second fluid delivery apparatus, the first and the second fluid delivery apparatuses being positioned above the conveyor device and arranged such that a gap exists between each of the first and second fluid delivery apparatuses and the first surface of the web, wherein the first and the second fluid delivery apparatuses are configured to deliver one or more fluids comprising divalent cadmium, divalent zinc, or trivalent indium onto the first surface of the web; and
a first fluid removal apparatus, the first fluid removal apparatus being positioned within a space arranged between the first and the second delivery apparatuses.

2. A system according to claim 1, wherein the first fluid removal apparatus comprises a suction device.

3. A system according to claim 1, further comprising one or more heating apparatus configured to heat the web as it undergoes the one or more processing steps.

4. A system according to claim 1, further comprising a second fluid removal apparatus comprising a suction device; wherein the second fluid removal apparatus is positioned to remove fluid delivered by the second fluid delivery apparatus.

5. A system according to claim 4, further comprising a rinse apparatus positioned adjacent to the second fluid removal apparatus and opposite the space arranged between the first and the second delivery apparatuses.

6. A system according to claim 1, wherein the one or more fluids comprises a solution containing a material comprising divalent cadmium.

7. A system according to claim 5, further comprising a drying apparatus positioned adjacent the rinse apparatus opposite the second fluid removal apparatus.

8. A process for forming a layer of material on a web, wherein the web has a first surface and a second surface opposite the first surface and the web is arranged in a horizontal orientation, the process comprising:
moving the web horizontally within an enclosure for carrying out one or more processing steps on the web;
delivering a first fluid comprising divalent cadmium, divalent zinc, or trivalent indium to the web via a first fluid delivery apparatus positioned above the web, wherein the first fluid delivery apparatus is arranged such that a gap exists between each of the first and second fluid delivery apparatuses and the first surface of the web;
removing a portion of the first fluid from the web via a first fluid removal apparatus;
subsequent to removing a portion of the first fluid, delivering a second fluid comprising divalent cadmium, divalent zinc, or trivalent indium to the web via a second fluid delivery apparatus positioned above the web; and
forming a layer of material on the web.

9. A process according to claim 8, further comprising heating the web subsequent to delivery of the first fluid.

10. A process according to claim 8, further comprising heating the web subsequent to delivery of the second fluid.

11. A process according to claim 8, wherein the layer of material formed on the web is CdS, In₃S₂, In(OH, S), ZnS, Zn(O, S), ZnCa(OH, S), ZnMg(OH, S), or CdO.

12. A process according to claim 8, wherein the first fluid comprises a material comprising divalent cadmium.

13. A process according to claim 8, wherein removing the portion of the first fluid from the web is conducted prior to formation of a substantial number of particles in the first fluid on the web.

14. A process according to claim 8, further comprising removing a portion of the second fluid from the web via a second fluid removal apparatus.

15. A process according to claim 8, wherein the first fluid delivery apparatus delivers fluid to the web at a rate sufficient to produce a fluid layer on the web having a depth of at least about 1 mm.

16. A process according to claim 10, wherein the layer of material formed on the web is CdS, In₃S₂, In(OH, S), ZnS, Zn(O, S), ZnCa(OH, S), ZnMg(OH, S), or CdO.

17. A process according to claim 16, wherein the first fluid comprises a material comprising divalent cadmium.

18. A process according to claim 17, wherein removing the portion of the first fluid from the web is conducted prior to formation of a substantial number of particles in the first fluid on the web.

19. A process according to claim 18, further comprising removing a portion of the second fluid from the web via a second fluid removal apparatus.

20. A system according to claim 2, further comprising a second fluid removal apparatus comprising a suction device; wherein the second fluid removal apparatus is positioned to remove fluid delivered by the second fluid delivery apparatus.
